(19) United States
(12) Patent Application Publication
(10) Pub. No.: US 2017/0018438 A1
(43) Pub. Date: Jan. 19, 2017

(54) PATTERN FORMING METHOD AND BAKE CONDITION DETERMINING METHOD

(71) Applicant: Kabushiki Kaisha Toshiba, Minato-ku (JP)

(72) Inventor: Yoshihiro YANAI, Yokkaichi (JP)

(73) Assignee: Kabushiki Kaisha Toshiba, Minato-ku (JP)

(21) Appl. No.: 14/846,088

(22) Filed: Sep. 4, 2015

Related U.S. Application Data
(60) Provisional application No. 62/191,704, filed on Jul. 13, 2015.

(51) Int. Cl. H01L 21/311; H01L 21/3105; H01L 27/115; H01L 21/768; H01L 21/027; H01L 21/02

(52) U.S. Cl. CPC H01L 21/31144; H01L 21/0273; H01L 21/02164; H01L 21/0217; H01L 27/11556; H01L 27/11582; H01L 21/76802; H01L 21/31058

(57) ABSTRACT

In a pattern forming method according to an embodiment, a work film to be processed is formed on a substrate, and a resist pattern is formed on the top of the work film. Then, the resist pattern is baked in the bake condition set at positions of the substrate. This forms first inclined surfaces those are not parallel to the top and side surfaces of the work film on the resist pattern. The first inclined surfaces are formed into shapes in accordance with the bake condition at positions of the substrate. Furthermore, the work film is etched using the resist pattern as a mask so as to form a second inclined surface on the work film.

### CROSS-REFERENCE TO RELATED APPLICATIONS

This application is based upon and claims the benefit of priority from U.S. Provisional Application No. 62/191,704, filed on Jul. 13, 2015; the entire contents of which are incorporated herein by reference.

### FIELD

The present embodiment broadly relates to a pattern forming method and a bake condition determining method.

### BACKGROUND

Some semiconductor devices include a three-dimensional memory cell. In such a three-dimensional memory cell, for example, a plurality of wiring layers is stacked while each of the wiring layers is connected to the upper layer side of a wiring layer. A method for forming such a connection structure is a method in which wiring layers are formed into a staircase pattern and contact layers are formed on the wiring layers in the staircase pattern.

However, multiple lithography processes are sometimes required in the existing technique in order to form such a staircase pattern. Furthermore, the process for forming the staircase into a desired shape costs time and money. Thus, there is a need to readily form a staircase pattern.

### BRIEF DESCRIPTION OF THE DRAWINGS

FIG. 1 is an explanatory diagram of the procedures of a pattern forming process according to an embodiment;

FIG. 2 is a flowchart of the procedures of a bake condition determining process according to an embodiment;

FIG. 3 is a diagram of exemplary distribution of etching rate ratios;

FIG. 4 is a diagram of an exemplary etching rate ratio at each position in a wafer plane;

FIG. 5 is a diagram of the relationship between an etching rate ratio and a wall surface angle;

FIG. 6 is a diagram of the relationship between a wall surface angle and a bake condition;

FIGS. 7A to 7C are explanatory diagrams of the relationship between the shape of a resist pattern and the shape of a processed work film;

FIG. 8 is a flowchart of a process for forming a semiconductor device according to an embodiment;

FIGS. 9A to 9E are explanatory diagrams of a process for forming a semiconductor device according to the embodiment; and

FIGS. 10A to 10C are explanatory diagrams of the shape of the work film etched with the resist patterns having the same shape at all of the positions in the wafer plane.

### DETAILED DESCRIPTION

A pattern forming method is provided according to the present embodiment. A work film to be processed is formed on a substrate, and a resist pattern is formed on the top of the work film in the pattern forming method. Then, the resist pattern is baked in the bake condition set at positions on the substrate. By this baking, first inclined surfaces those are not parallel to the top and side surfaces of the work film are formed on the resist pattern. The first inclined surfaces are formed into shapes in accordance with the bake condition at positions on the substrate. Furthermore, etching the work film using the resist pattern as a mask forms a second inclined surface on the work film.

The pattern forming method and bake condition determining method according to the embodiment will be described in detail with reference to the appended drawings. Note that the present invention is not limited to the embodiment.

### Embodiment

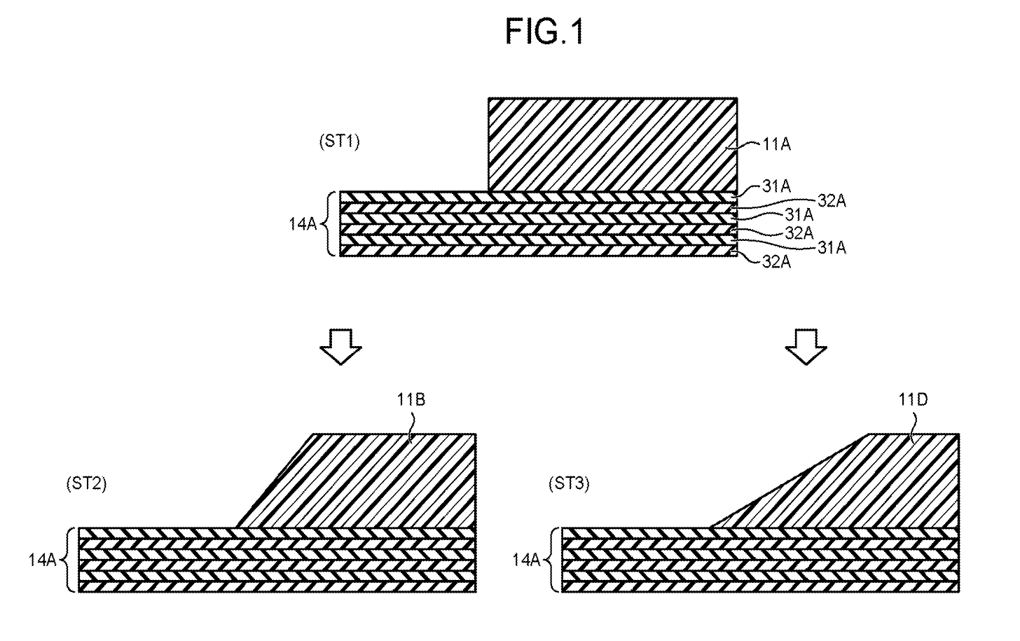

FIG. 1 is an explanatory diagram of the procedures of a pattern forming process according to the embodiment. When a semiconductor device (for example, a three-dimensional memory) includes a memory cell pattern that is a stacked structure, strings are typically formed in a direction perpendicular to the surface of the substrate. Thus, wires are drawn around the region in which the memory cells are formed. A contact electrode working as a wire is formed on each of the layers in a staircase pattern.

Such a semiconductor device includes a memory cell pattern in which a plurality of memory layers is stacked, and a staircase pattern formed by wiring layers. For example, the pattern forming process according to the present embodiment is used to form the staircase pattern.

A work film (film to be processed) (processing film) 14A is formed on the substrate such as a wafer. The work film 14A is a film to be processed in a pattern forming process. The work film 14A is a plurality of stacked insulation layers made of silicon oxide 31A and silicon nitride 32A (SiO/SiN). In other words, the layers of silicon oxide 31A and silicon nitride 32A are alternately stacked on the wafer, and the stacked layers form the work film 14A that is a stacked body. The layers of silicon nitride 32A are replaced with wiring layers by the subsequent process.

After the work film 14A is formed, a resist pattern 11A is formed on a part of the top of the work film 14A (ST1). When the resist pattern 11A is formed, a resist film is exposed and developed. When the wafer is baked after the development, the resist pattern 11A changes the shape in accordance with the bake condition. Specifically, the side surface of the resist pattern 11A is inclined from the vertical direction to an oblique direction (the side surface of the vertical direction is change to a side surface of an oblique direction). This inclination makes the resist pattern 11A have a trapezoidal cross-sectional surface. The bake condition in the present embodiment is, for example, the baking temperature.

For example, when being baked (reflowed) in a first bake condition (at a low temperature), the resist pattern 11A becomes a resist pattern 11B of which side surface is the nth (n is a natural number) inclined surface (ST2). Alternatively, when being baked in a second bake condition (at a high temperature), the resist pattern 11A becomes a resist pattern 11D of which side surface is the mth (m is a natural number) inclined surface (ST3). Baking the resist pattern 11A as described above changes the side surface in the vertical direction to the side surface inclined in accordance with the bake condition. The inclined surface is not parallel to the top and side surfaces of the work film 14A.

Note that the baked resist pattern (for example, the resist patterns 11B, 11D, or a resist pattern 11C to be described below) is sometimes referred to as a resist pattern 11X in the following description.

The appropriate shape of the resist pattern 11X varies depending on the etching rate ratio between the resist pattern 11X and the work film 14A. The ratio of the etching rate of the resist pattern 11X to the etching rate of the work film 14A is described as the etching rate ratio in the present embodiment. Note that the etching rate ratio can be the ratio of the etching rate of the work film 14A to the etching rate of the resist pattern 11X.

For example, when the etching rate ratio of the work film 14A is higher than a predetermined value (a reference value), an inclined surface having an inclination angle (the wall surface angle to be described below) larger than a predetermined angle (a reference angle) is the inclined surface appropriate to the resist pattern 11X.

On the other hand, when the etching rate ratio of the work film 14A is lower than the predetermined value, an inclined surface having a wall surface angle smaller than the predetermined angle is the inclined surface appropriate to the resist pattern 11X.

By the way, the etching rate ratio between the resist pattern 11X and the work film 14A is distributed in the wafer plane. Thus, a bake condition is set depending on each of the etching rate ratios in the wafer plane in the present embodiment.

For example, a first bake condition for forming the nth inclined surface is set at a first position (a first region) having a first etching rate ratio on the wafer. Meanwhile, a second bake condition for forming the mth inclined surface is set at a second position (a second region) having a second etching rate ratio on the wafer.

Subsequently, the first position of the wafer is baked in the first bake condition. This bake forms the nth inclined surface at the first position. Meanwhile, the second position of the wafer is baked in the second bake condition. This bake forms the mth inclined surface at the second position.

Accordingly, a resist pattern 11X having the nth inclined surface is formed at the position having the first etching rate ratio on the wafer. Meanwhile, a resist pattern 11X having the mth inclined surface is formed at the position having the second etching rate ratio on the wafer.

After that, the wafer is etched from above the resist pattern 11X. This etching transfers the resist pattern 11X to the work film 14A. For example, the work film 14A is processed at the first position on the wafer at the first etching rate ratio using the resist pattern 11X having the nth inclined surface as a mask. Meanwhile, the work film 14A is processed at the second position on the wafer at the second etching rate ratio using the resist pattern 11X having the mth inclined surface as a mask. As a result, processed patterns having the same shape are formed at the first position and the second position on the wafer.

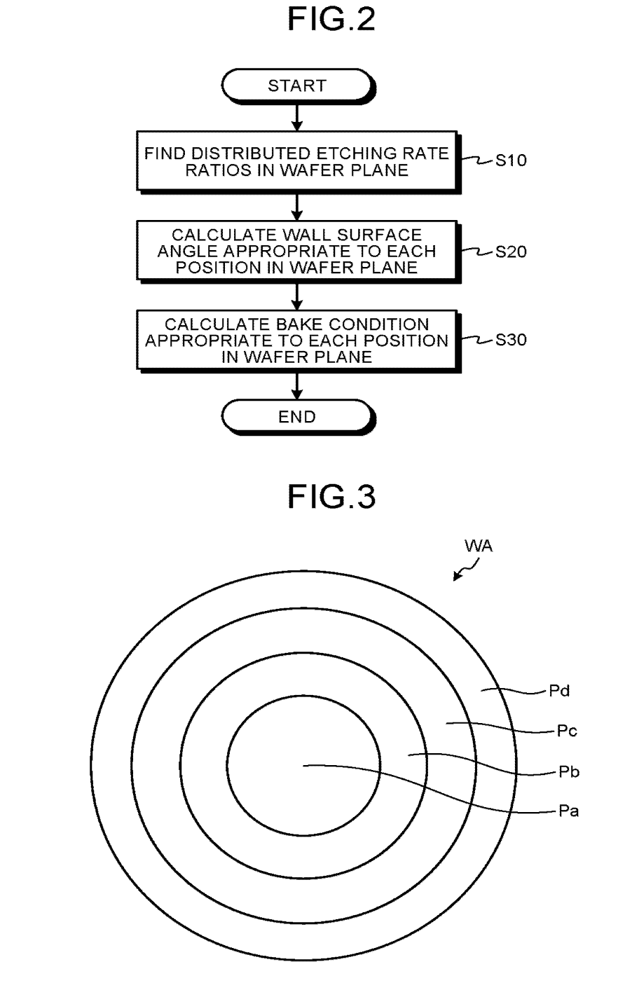

A process for determining a bake condition will be described next. FIG. 2 is a flowchart of the procedures of a bake condition determining process according to the embodiment. When a bake condition is determined, the etching rate ratio, which is between the resist pattern 11X and the work film 14A and is distributed in the wafer plane, is calculated (step S10). Each of the distributed etching rate ratios (distribution of the etching rate ratios) is determined in accordance with the etching condition, the etching device (etcher), the characteristics of the work film 14A, or the characteristics of the resist pattern 11X.

FIG. 3 is a diagram of exemplary distribution of etching rate ratios. A wafer WA includes various distributed etching rate ratios at the positions in the wafer plane. For example, the etching ratio in the illustrated first region (a position Pa) in the wafer plane is the first etching rate ratio, and the etching ratio in the illustrated second region (a position Pb) in the wafer plane is the second etching rate ratio. Meanwhile, the etching ratio in the illustrated third region (a position Pc) in the wafer plane is the third etching rate ratio, and the etching ratio in the illustrated fourth region (a position Pd) in the wafer plane is the fourth etching rate ratio. The first region is, for example, a circular region, and the second to fourth regions are, for example, annular region. Then, the center of the first region is identical to the centers of the second to fourth regions. Thus, a bake condition is set at each distance from the center of the wafer WA in this example.

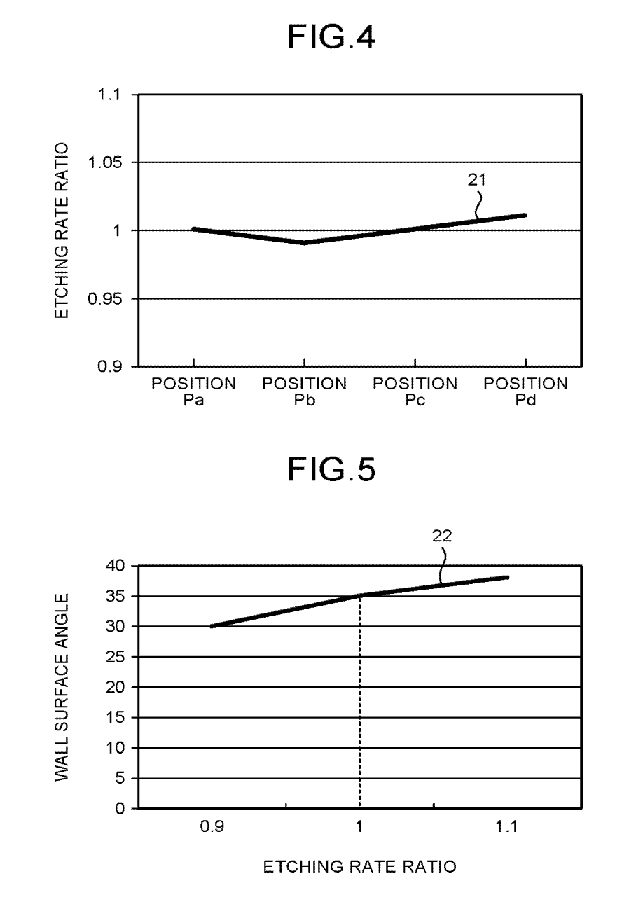

FIG. 4 is a diagram of an exemplary etching rate ratio at each position in the wafer plane. The positions in the wafer plane are shown on the horizontal axis and the etching rate ratios are shown on the vertical axis in FIG. 4. FIG. 4 illustrates an etching rate ratio characteristic 21 when the etching rate ratio at the position Pa is a reference etching rate ratio (the reference value=one).

For example, the etching rate ratio at the position Pb is lower than the etching rate ratio at the position Pa, and the etching rate ratio at the position Pd is higher than the etching rate ratio at the position Pa. Furthermore, the etching rate ratio at the position Pc is identical to the etching rate ratio at the position Pa.

Accordingly, the etching rate of the resist pattern 11X at the position Pd is higher than the etching rates at the positions Pa and Pc. Meanwhile, the etching rate of the resist pattern 11X at the position Pb is lower than the etching rates at the positions Pa and Pc. Furthermore, the etching rate of the resist pattern 11X at the position Pc is identical to the etching rate at the position Pa.

After the distributed etching rate ratios are found, an inclination angle appropriate to the side wall surface of the resist pattern 11X is calculated at each of the positions in the wafer plane (step S20). The inclination angle to the side wall surface (hereinafter, referred to as a wall surface angle) is the angle between the side wall surface and bottom surface of the resist pattern 11X. Accordingly, the resist pattern 11A has a wall surface angle of 90 degrees before the resist pattern 11A is baked, and the baked resist pattern 11X has a wall surface angle smaller than 90 degrees.

FIG. 5 is a diagram of the relationship between an etching rate ratio and a wall surface angle. The etching rate ratios are shown on the horizontal axis and the wall surface angles are shown on the vertical axis in FIG. 5. The etching rate ratios shown on the horizontal axis in FIG. 5 correspond to the etching rate ratios shown on the horizontal axis in FIG. 3. FIG. 5 illustrates the wall surface angles corresponding to the etching rate ratios (a correspondence relationship 22). The correspondence relationship 22 is the relationship between the etching rate ratio and the wall surface angle required to process the work film 14A into a desired shape.

As the illustrated correspondence relationship 22, the wall surface angle needs to increase as the etching rate ratio increases. For example, the etching rate ratios at the positions Pa and Pc are identical to the reference value (the reference value=one), and the wall surface angles are each 35 degrees. The etching rate ratio at the position Pb is lower than the reference value. Thus, the wall surface angle needs to be smaller than 35 degrees. The etching rate ratio at the position Pd is higher than the reference value. Thus, the wall surface angle needs to be larger than 35 degrees. A wall surface angle appropriate to each of the positions in the wafer plane is calculated in accordance with the relationships illustrated in FIG. 4 and FIG. 5 in the present embodiment.

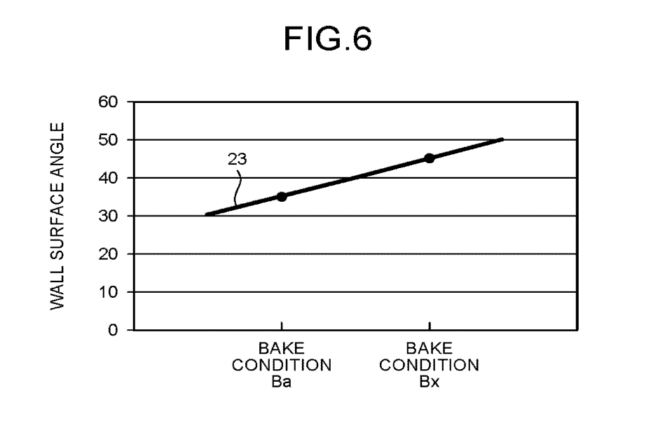

FIG. 6 is a diagram of the relationship between a wall surface angle and a bake condition. The bake conditions are shown on the horizontal axis and the wall surface angles are shown on the vertical axis in FIG. 6. The wall surface angles shown on the vertical axis in FIG. 6 correspond to the wall surface angles shown on the vertical axis in FIG. 5. FIG. 6 illustrates the bake conditions corresponding to the wall surface angles (a correspondence relationship 23). For example, a wall surface angle of 35 degrees corresponds to a bake condition Ba, and a wall surface angle of 45 degrees corresponds to a bake condition Bx.

The wall surface angles at the positions Pa and Pc are each 35 degrees. Thus, the bake condition Ba is set at the positions Pa and Pc. When the bake condition is the baking temperature, a baking temperature of Ta degrees that is the reference value of the baking temperature is set as the bake condition Ba. In other words, the baking temperature of Ta degrees is set at the positions Pa and Pc. Meanwhile, the wall surface angle at the position Pb is smaller than those at the positions Pa and Pc. Thus, a baking temperature higher than the baking temperature of Ta degrees is set at the position Pb. Meanwhile, the wall surface angle at the position Pd is larger than those at the positions Pa and Pc. Thus, a baking temperature lower than the baking temperature of Ta degrees is set at the position Pd. A bake condition appropriate to each of the positions in the wafer plane is calculated in accordance with the relationships illustrated in FIG. 5 and FIG. 6 in the present embodiment (step S30).

To determine a bake condition, the relationships illustrated in FIGS. 4 to 6 are prepared as described above. Then, the etching rate ratio at a position Px (the Px is any one of Pa to Pd) is derived in accordance with the relationship in FIG. 4. Furthermore, the wall surface angle at the position Px is set in accordance with the etching rate ratio at the position Px and the relationship illustrated in FIG. 5. Furthermore, the bake condition at the position Px is set in accordance with the wall surface angle at the position Px and the relationship illustrated in FIG. 6. In other words, a wall surface angle appropriate to each of the positions in the wafer plane is set in accordance with the correspondence relationship between the etching rate ratio and the wall surface angle. Then, a bake condition appropriate to each of the positions in the wafer plane is calculated in accordance with the correspondence relationship between the wall surface angle and the bake condition.

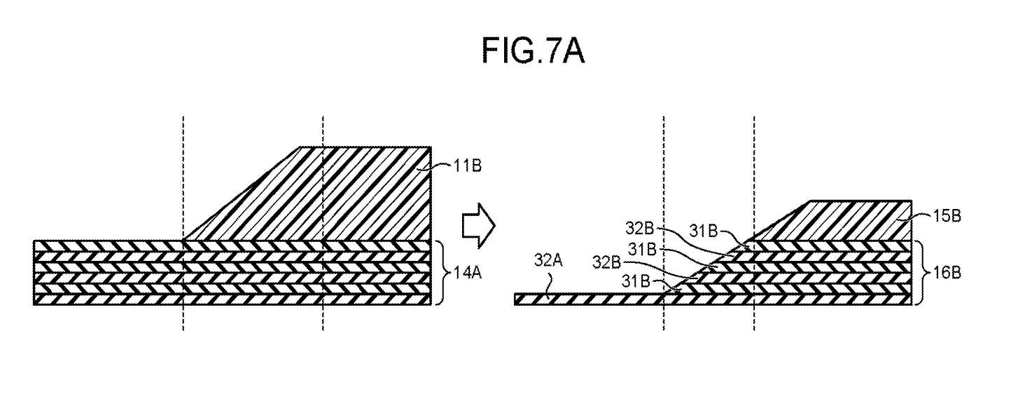

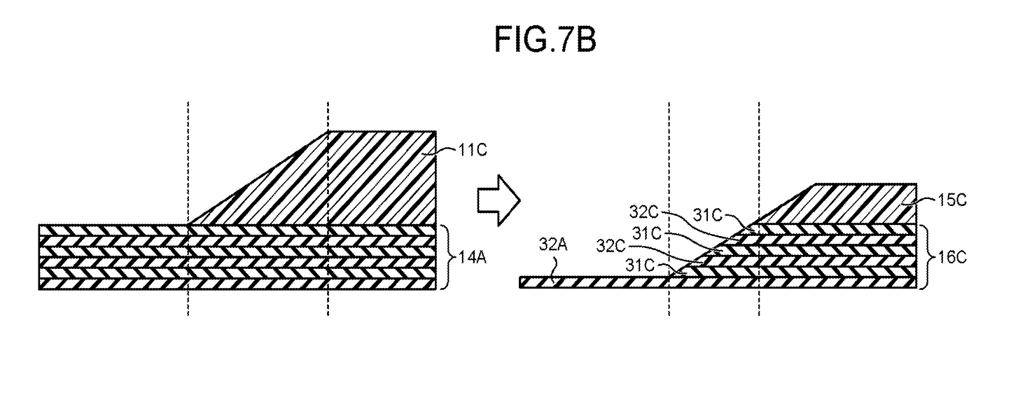

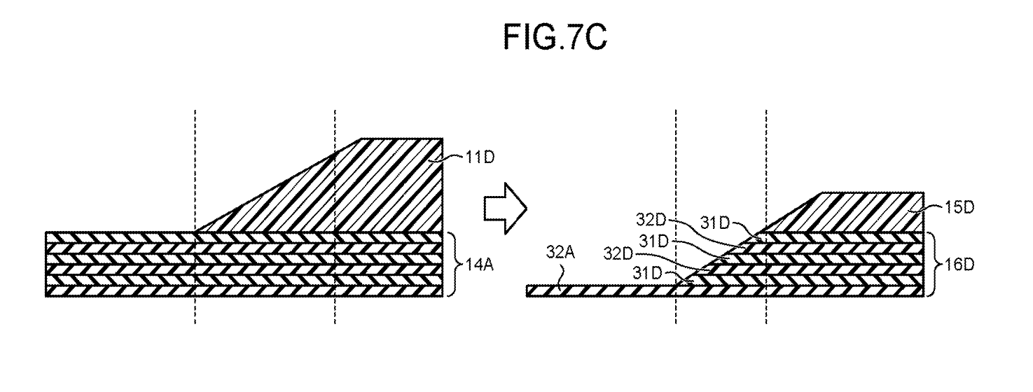

The relationship between the shape of the resist pattern 11X and the shape of the processed work film 14A will be described hereinafter. FIGS. 7A to 7C are explanatory diagrams of the relationship between the shape of a resist pattern and the shape of a processed work film. The resist pattern 11B illustrated in FIG. 7A is the resist pattern, in a case of the wafer WA is baked at a low temperature. The resist pattern 11C illustrated in FIG. 7B is the resist pattern, in a case of the wafer WA is baked at a middle temperature (a reference temperature). The resist pattern 11D illustrated in FIG. 7C is the resist pattern, in a case of the wafer WA is baked at a high temperature.

The resist pattern 11X is formed such that the resist pattern 11X has a cross-sectional surface in accordance with the baking temperature. The reference shape of the resist pattern 11X is the shape that can stably be processed in the etching at the reference etching rate ratio among the various resist patterns 11X. The baking temperature used to form the resist pattern 11X having the reference shape is the reference temperature.

The resist pattern 11C illustrated in FIG. 7B is the reference resist pattern baked at the reference temperature. The resist pattern 11B illustrated in FIG. 7A is the resist pattern baked at a temperature lower than the reference temperature. The resist pattern 11D illustrated in FIG. 7C is the resist pattern baked at a temperature higher than the reference temperature.

Thus, the resist pattern 11B illustrated in FIG. 7A has an inclination angle larger than the inclination angle of the resist pattern 11C illustrated in FIG. 7B. The resist pattern 11D illustrated in FIG. 7C has an inclination angle smaller than the inclination angle of the resist pattern 11C illustrated in FIG. 7B.

The resist pattern 11C is formed at a position at which the etching rate ratio is identical to the reference value in the wafer plane. Meanwhile, the resist pattern 11B is formed at a position at which the etching rate ratio is higher than the reference value in the wafer plane. The resist pattern 11D is formed at a position at which the etching rate ratio is lower than the reference value in the wafer plane.

Etching the work film 14A using each of the resist patterns 11B to 11D illustrated in FIGS. 7A to 7C as a mask forms the work film 14A into each of the work films 16B to 16D having an inclined surface. Note that the work films 16B to 16D illustrated in FIGS. 7A to 7C are in process. Thus, further etching the work films 16B to 16D changes all the layers of silicon oxide 31A to the layers of silicon oxide 31B, and all the layers of silicon nitride 32A to the layer of silicon nitride 32B.

Further etching each of the resist patterns 11B to 11D reduces the film thickness and top surface area of each of the resist patterns 11B to 11D, and changes the resist patterns 11B to 11D to the resist patterns 15B to 15D, respectively. Note that the resist patterns 11B to 11D illustrated in FIGS. 7A to 7C are in process. Thus, further etching each of the resist patterns 11B to 11D further reduces the film thickness and top surface area of each of the resist patterns 11B to 11D. The region in which the inclined surface is formed on each of the work films 16B to 16D is, for example, the region in which a gate electrode is drawn in a stacked-layer semiconductor storage device.

Processing the work film 14A using the resist pattern 11B changes the layer of silicon oxide 31A to the layer of silicon oxide 31B having an inclined side surface. Processing the work film 14A changes the layer of silicon nitride 32A to the layer of silicon nitride 32B having an inclined side surface. This processing forms a work film 16B having an inclined side surface.

Processing the work film 14A using the resist pattern 11C changes the layer of silicon oxide 31A to the layer of silicon oxide 31C having an inclined side surface. Processing the work film 14A changes the layer of silicon nitride 32A to the layer of silicon nitride 32C having an inclined side surface. This processing forms a work film 16C having an inclined side surface.

Processing the work film 14A using the resist pattern 11D changes the layer of silicon oxide 31A to the layer of silicon oxide 31D having an inclined side surface. Processing the work film 14A changes the layer of silicon nitride 32A to the layer of silicon nitride 32D having an inclined side surface. This processing forms a work film 16D having an inclined side surface.

The resist pattern 11C has a shape that can stably be processed. The etching rate ratio is identical to the reference value at the position at which the resist pattern 11C is formed. Thus, the work film 16C is formed into a desired shape. The work film 16C includes, for example, a side wall that is at the reference wall surface angle. The ratio between the dimension of the bottom of the inclined surface of the work film 16C (for example, 60000 nm), and the film thickness of the work film 16C (for example, 7000 nm) is the reference value.

The resist pattern 11B has a wall surface angle larger than the wall surface angle of the resist pattern 11C. Furthermore, the etching rate ratio is higher than the reference value at the position at which the resist pattern 11B is formed. Thus, the work film 16B has the same shape as the work film 16C does.

The resist pattern 11D has a wall surface angle smaller than the wall surface angle of the resist pattern 11C. Furthermore, the etching rate ratio is lower than the reference value at the position at which the resist pattern 11D is formed. Thus, the work film 16D has the same shape as the work film 16C does.

As described above, the resist patterns 11B to 11D having wall surface angles in accordance with the etching rate ratios are formed on the wafer WA. Thus, the work films 16B to 16D are formed into desired shapes. Specifically, the work films 16B to 16D have the same terrace width of a staircase (the parts forming terraces have the same dimension of the bottom and the same film thickness).

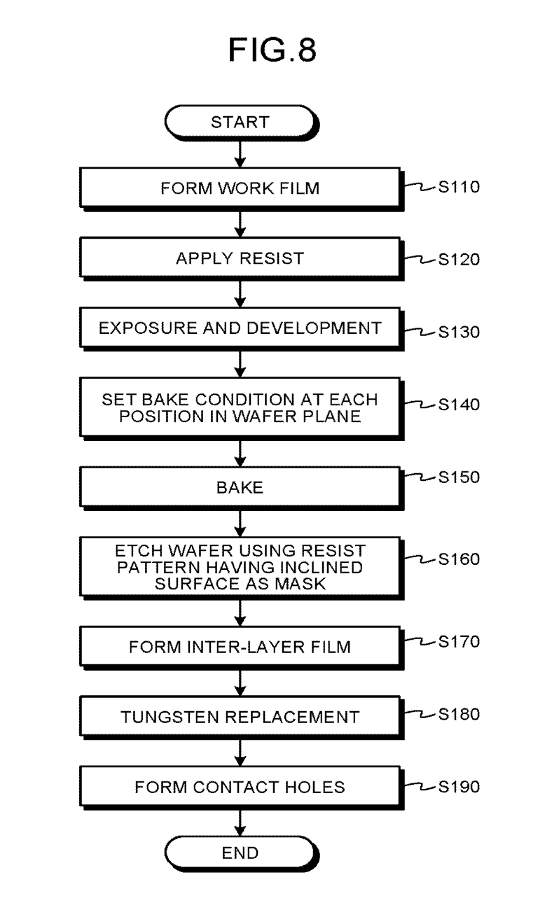

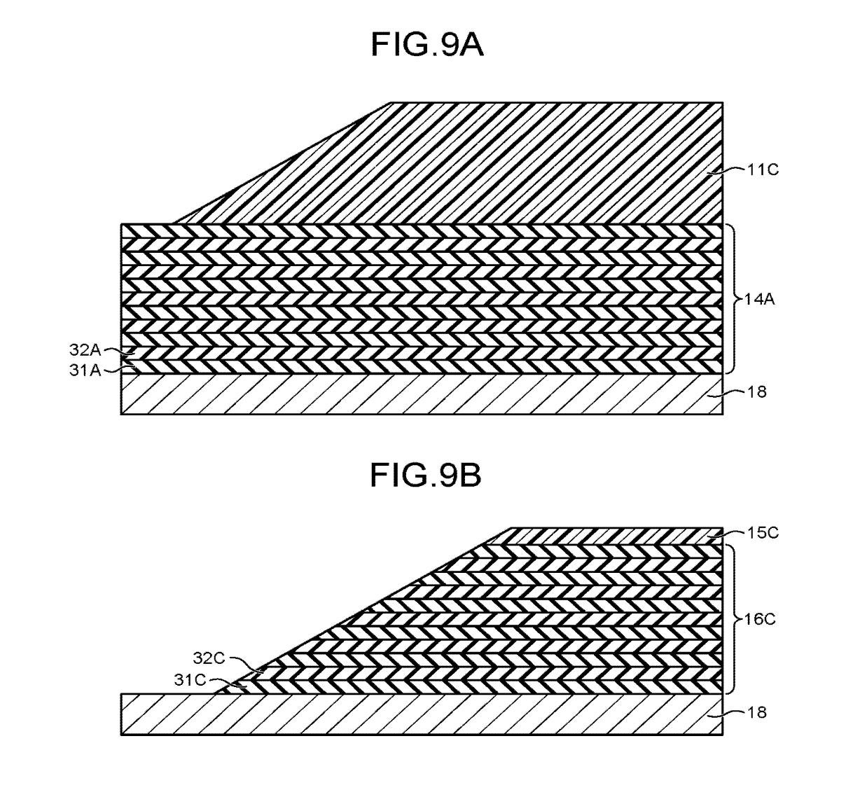

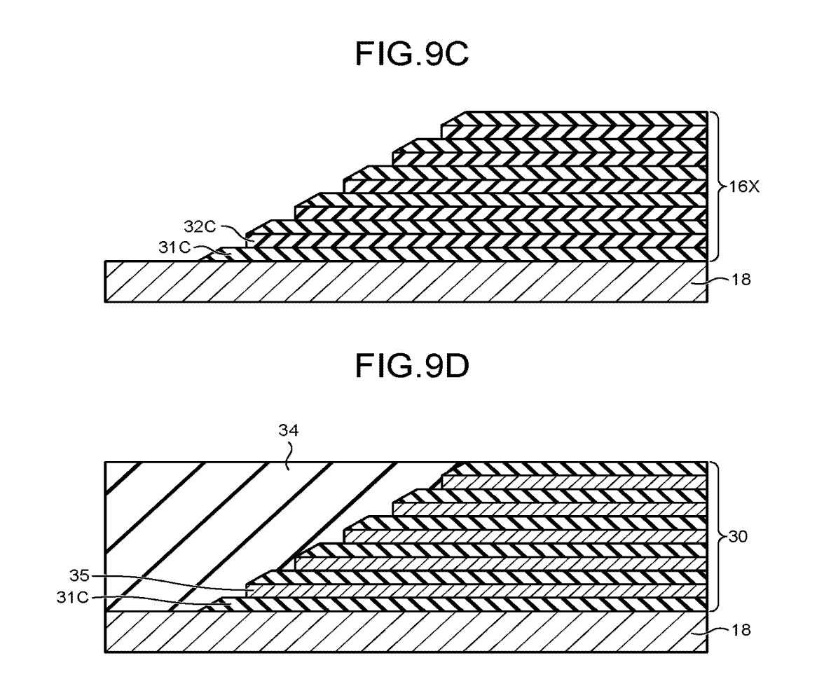

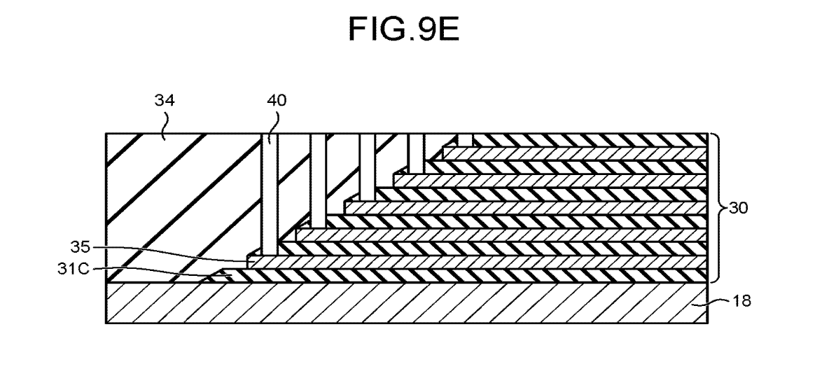

A process for forming a semiconductor device will be described next. FIG. 8 is a flowchart of a process for forming a semiconductor device according to the embodiment. FIGS. 9A to 9E are explanatory diagrams of a process for forming a semiconductor device according to the embodiment. FIG. 8 and FIGS. 9A to 9E illustrate the procedures for forming contact holes in a thick film in the process for forming the semiconductor device.

As illustrated in FIG. 9A, a lower layer film 18 is formed on the wafer WA, and the work film 14A is subsequently formed on the lower layer film 18 (step S110). A resist is subsequently applied on the work film 14A (step S120). Furthermore, the resist is exposed and developed (step S130). This forms a resist pattern.

A bake condition is set at each of the positions in the plane of the wafer WA (step S140). At that time, the bake condition is set with the process for determining a bake condition illustrated in FIG. 2. After the bake condition is set, the wafer WA is baked in the bake condition (step S150). This forms a resist pattern 11X having a wall surface angle (an inclined surface) in accordance with the etching rate ratio. An example in which the resist pattern 11X is the resist pattern 11C will be described hereinafter.

The film thickness of the resist pattern 11C is, for example, 7000 nm and the film thickness of the work film 14A is, for example, 6000 nm. The film thickness of a layer of silicon oxide 31A is, for example, 30 nm, and the film thickness of a layer of silicon nitride 32A is, for example, 30 nm. In this example, stacking 100 layers formed by the silicon oxide 31A and the silicon nitride 32A alternately forms a work film 14A.

After that, the wafer WA is etched by anisotropic etching using the resist pattern 11C having an inclined surface as a mask (step S160). In this example, the etching rate of the resist pattern 11C, the silicon oxide 31A, and the silicon nitride 32A is in the ratio of 1:1:1.

Etching the wafer WA as described above transfers the resist pattern 11C to the work film 16C as illustrated in FIG. 9B. This transfer changes the resist pattern 11C to the resist pattern 15C, and the work film 14A to the work film 16C having an inclined side surface.

Similarly, the work film 16B having the same shape as the work film 16C is formed at the position of the resist pattern 11B, and the work film 16D having the same shape as the work film 16C is formed at the position of the resist pattern 11D. This formation forms the work films having the same shape (the work films 16B to 16D in a staircase pattern) at the positions on the wafer WA, respectively.

Furthermore, the silicon nitride 32A is etched from above the work film (in this example, the work film 16C in a staircase pattern) by Reactive Ion Etching (RIE). This etches the silicon nitride 32A using the silicon oxide 31A as a mask. Specifically, as illustrated in FIG. 9C, the exposed part of the silicon nitride 32A is selectively removed from the work film 16C. This removal changes the work film 16C to the work film 16X in which an end (a part of the inclined surface) of the silicon nitride 32A is removed. The work film 16X has a staircase-patterned structure using the silicon oxide 31A as a terrace.

After the silicon nitride 32A is etched, the resist pattern 15C is removed. Removing a part of the silicon nitride 32A and the resist pattern 15C on the wafer WA as described above forms the work film 16X. The work film 16X has a staircase structure such that a contact electrodes is formed on each terrace of the staircase.

After the resist pattern 15C is removed, an inter-layer film 34 is formed from the top of the work film 16X as illustrated in FIG. 9D (step S170). After that, grooves (not illustrated) are formed on the inter-layer film 34. Subsequently, the layers of silicon nitride 32C are removed from the work film 16X by wet etching using heat phosphoric acid. The parts that are the layers of silicon nitride 32C removed from the work film 16X are filled with electrode films (wiring layers made of metal films) 35 made of tungsten. In other words, the silicon nitride 32C is replaced with tungsten by tungsten replacement (step S180). This changes the work film 16X to the work film 30 in which the electrode film 35 that works as a cell gate electrode is embedded. A plurality of layers of electrode films 35 is formed on the work film 16X, and thus the work film 16X works as stacked cell gate electrodes.

Furthermore, a mask pattern (not illustrated) is formed on the work film 30. The mask pattern includes an opening portion at a position corresponding to each of the terraces in the staircase pattern. These opening portions are patterns used to form the contact holes. After that, the inter-layer film 34 and the silicon oxide 31C just under the inter-layer film 34 are selectively etched by the RIE method using the mask pattern as a mask.

This etching forms a plurality of contact holes 40 through the inter-layer film 34 and the silicon oxide 31C as illustrated in FIG. 9E (step S190). The contact holes 40 have different depths from the top surface of the inter-layer film 34. Each of the contact holes penetrates the inclined part of the silicon oxide 31C and the inter-layer film 34, and reaches the electrode film 35 of each terrace.

For example, the first to Nth contact holes are formed on the first to Nth (N is a natural number) layers of the electrode films 35, respectively. Each of the first to Nth contact holes is a pattern that penetrates the inter-layer film 34 and reaches the work film 30 through each of the inclined surfaces of the work films 30. After the first to Nth contact holes are formed, a contact electrode (wiring plug) is embedded in each of the contact holes.

As described above, performing a set of a lithography process and an etching process can form a contact structure in a staircase pattern in the present embodiment. This can drastically reduce the cost to form a contact structure in a staircase pattern.

The shape of a work film etched with resist patterns having the same shape at all of the positions in the wafer plane regardless of the etching rate ratios in the wafer plane will be described hereinafter.

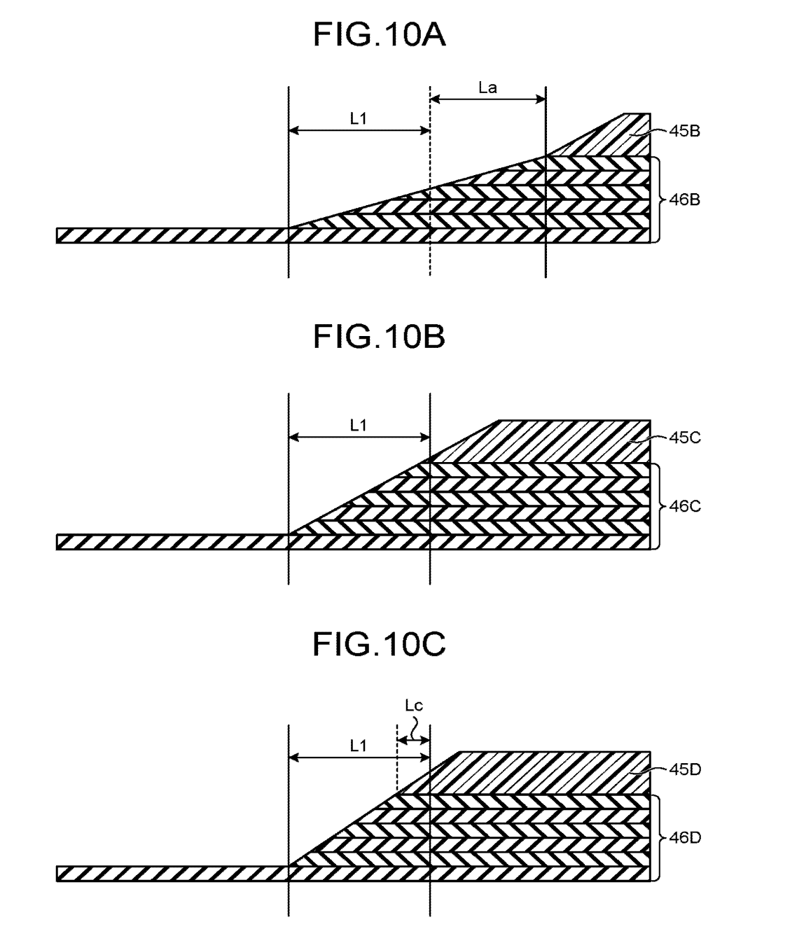

FIGS. 10A to 10C are explanatory diagrams of the shape of a work film etched with resist patterns having the same shape at all of the positions in the wafer plane. FIGS. 10A to 10C illustrate work films 46B to 46D etched with the resist patterns 11C having the same shape at all of the positions in the wafer plane.

FIG. 10B illustrates the work film 46C etched with the resist pattern 11C at the etching rate ratio identical to the reference value. Etching the work film 14A using the resist pattern 11C as a mask at the position at which the etching rate ratio is identical to the reference value forms the resist pattern 11C and the work film 14A into desired shapes. As a result, the resist pattern 11C becomes a resist pattern 45C having the same shape as the resist pattern 15C. Meanwhile, the work film 14A becomes the work film 46C having the same shape as the work film 16C.

FIG. 10A illustrates the work film 46B etched with the resist pattern 11C at the etching rate ratio higher than the reference value. Etching the work film 14A using the resist pattern 11C as a mask at the position at which the etching rate ratio is higher than the reference value increases the decrease in amount of the resist pattern 11C and the work film 14A. As a result, the resist pattern 11C becomes a resist pattern 45B of which top surface has an area smaller than the area of the top surface of the resist pattern 15C (the resist pattern 45C). Meanwhile, the work film 14A becomes a work film 46B of which wall surface angle is smaller than the wall surface angle of the work film 16C (the work film 46C).

FIG. 10C illustrates the work film 46C etched with the resist pattern 11C at the etching rate ratio lower than the reference value. Etching the work film 14A using the resist pattern 11C as a mask at the position at which the etching rate ratio is lower than the reference value reduces the decrease in amount of the resist pattern 11C and the work film 14A. As a result, the resist pattern 11C becomes a resist pattern 45D of which top surface has an area larger than the area of the top surface of the resist pattern 15C (the resist pattern 45C). Meanwhile, the work film 14A becomes a work film 46D of which wall surface angle is larger than the wall surface angle of the work film 16C (the work film 46C).

When the work films 46B to 46D are etched with the resist pattern 11C having the same shape at all of the positions in the wafer plane as described above, the shapes of the work films 46B to 46D are different from each other depending on the value of the etching rate ratio.

On the other hand, each of the resist patterns 11B to 11D having a shape depending on the etching rate ratio is formed at each of the positions in the plane of the wafer WA in the present embodiment. Then, the work film 14A is etched with the resist patterns 11B to 11D. This etching can form the work films 16B to 16D having the same shape in the plane of the wafer WA.

The work films 16B to 16D having the same shape can be formed in the plane of the wafer WA. This formation can prevent the positions of terraces in the staircase from misalignment caused by the unevenness in etching in the plane of the wafer WA. As a result, the contact electrodes can electrically correctly be connected to the electrode films 35.

As described above, the pattern forming method and bake condition determining method according to the present embodiment are used, for example, to form a vertical channel three-dimensional memory in which a channel is formed into a tube in a NAND MOSFET. For example, when the three-dimensional memory is a Bit Cost Scalable (BiCS) three-dimensional flash memory, the electrode film 35 working as the wiring layer corresponds to a gate wiring layer of the cell.

The resist pattern 11A is baked in the bake condition set at each of the positions on the wafer WA in the present embodiment. Furthermore, an inclined surface that is not parallel to the top and side surfaces of the work film 14A is formed into a shape in accordance with the bake condition on the resist pattern 11A. The work film 14A is etched using the resist patterns 11B to 11D as masks. This etching can form the work films 16B to 16D each having an inclined surface into the same shape in the plane of the wafer WA. Thus, the work films 16B to 16D each having an inclined surface can easily be formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A pattern forming method comprising:
forming a work film to be processed on a substrate;
forming a resist pattern on a top of the work film;
baking the resist pattern in a bake condition set at positions on the substrate;
forming a first inclined surfaces on the resist pattern at the positions on the substrate, the first inclined surfaces being not parallel to top and side surfaces of the work film, the first inclined surfaces having shapes in accordance with the bake condition;
etching the work film using the resist pattern as a mask; and
forming second inclined surfaces on the work film.

2. The pattern forming method according to claim 1, wherein the bake condition is set at the positions on the substrate in accordance with an etching rate ratio between the resist pattern and the work film.

3. The pattern forming method according to claim 2, wherein, when the bake condition is set,
a first inclination angle of the first inclined surfaces is set in accordance with the etching rate ratio, and the bake condition is set in accordance with the first inclination angle.

4. The pattern forming method according to claim 3, wherein the first inclination angle is set in accordance with first correspondence relationship information indicating a correspondence relationship between the etching rate ratio and the first inclination angle.

5. The pattern forming method according to claim 3, wherein the bake condition is set in accordance with second correspondence relationship information indicating a correspondence relationship between the first inclination angle and the bake condition.

6. The pattern forming method according to claim 1, wherein second inclination angles of the second inclined surfaces are identical in a plane of the substrate.

7. The pattern forming method according to claim 1, wherein
the bake condition is a baking temperature.

8. The pattern forming method according to claim 1, wherein
the bake condition is set for distances from a center of the substrate.

9. The pattern forming method according to claim 1, wherein
the work film is a film formed by stacked layers and used to form a three-dimensional memory.

10. The pattern forming method according to claim 1, the method further comprising:
forming an inter-layer film on the top of the work film after forming the second inclined surfaces;
etching the inter-layer film; and
forming a contact hole on the inter-layer film, the contact hole penetrating the inter-layer film, and reaching the work film through the second inclined surface.

11. The pattern forming method according to claim 1, wherein
the resist pattern is formed by an exposed and developed resist film.

12. A bake condition determining method comprising:
setting a first inclination angle at positions on a substrate, the first inclination angle being obtained by inclining a side surface of a resist pattern formed on a top of a work film on the substrate such that the side surface becomes first inclined surfaces, the first inclined surfaces being not parallel to top and side surfaces of the work film; and
setting a bake condition for the resist pattern at the positions on the substrate in accordance with the first inclination angle.

13. The bake condition determining method according to claim 12, wherein the bake condition is set at the positions on the substrate in accordance with an etching rate ratio between the resist pattern and the work film.

14. The bake condition determining method according to claim 13, wherein, when the bake condition is set,
the first inclination angle is set in accordance with the etching rate ratio, and the bake condition is set in accordance with the first inclination angle.

15. The bake condition determining method according to claim 14, wherein the first inclination angle is set in accordance with first correspondence relationship information indicating a correspondence relationship between the etching rate ratio and the first inclination angle.

16. The bake condition determining method according to claim 12, wherein the bake condition is set in accordance with second correspondence relationship information indicating a correspondence relationship between the first inclination angle and the bake condition.

17. The bake condition determining method according to claim 12, the method further comprising:
setting the bake condition such that second inclination angles of second inclined surfaces are identical when the work film is etched using the resist pattern as a mask, the second inclined surfaces being formed on the work film.

18. The bake condition determining method according to claim 12, wherein
the bake condition is a baking temperature.

19. The bake condition determining method according to claim 12, wherein
the bake condition is set for distances from a center of the substrate.

20. The bake condition determining method according to claim 12, wherein
the work film is a film formed by stacked layers and used to form a three-dimensional memory.
